(19) United States
(12) Patent Application Publication
(10) Pub. No.: US 2002/0004259 A1
(43) Pub. Date: Jan. 10, 2002

(54) SEMICONDCTOR DEVICE WITH MULTI-LEVEL INTERCONNECT HAVING EMBEDDED LOE DIELECTRIC CONSTANT LAYER AND PROCESS FOR MAKING SAME

(75) Inventors: RUICHEN LIU, WARREN, NJ (US); HELEN LOUISE MAYNARD, SOMERSET, NJ (US); CHEIN-SHING PAI, BRIDGEWATER, NJ (US)

Correspondence Address: CHRISTOPHER A HAMATY, MORGAN & FINNEGAN, 345 PARK AVENUE, NEW YORK, NY, 10154

(73) Assignee: Lucent Technologies, Inc.

(21) Appl. No.: 09/401,409

(22) Filed: Sep. 22, 1999

(51) Int. Cl. H01L 21/44; H01L 21/48; H01L 21/50; H01L 21/4763

(52) U.S. Cl. 438/118

(57) ABSTRACT

A process for fabricating a multi-layer interconnect in which an organic low-k material is formed over a topographic substrate. An insulator such as silicon dioxide is formed over the organic low-k material. The insulator is planarized. Contact holes or vias are then etched in the two-layer stack.

### BACKGROUND OF THE INVENTION

1. Field of the Invention

The invention relates to a semiconductor device embodying a multi-level interconnect having an embedded low-dielectric constant layer.

2. Description of the Related Art

As integrated circuits continue to be driven to operate at higher frequencies, it is important to reduce the delay time associated with on-chip signal propagation. Current device construction technologies use metal lines (typically a metal stack consisting primarily of aluminum) to distribute the signals, and the metal lines are insulated from each other by silicon dioxide (SiO₂). The signal propagation delay time would be reduced, however, if SiO₂ is replaced by a material that has a low dielectric constant (low “k”). There are many difficult integration problems associated with replacing SiO₂ (a well-understood and well-characterized material) with an alternative material. Such alternative material should be incorporated so as to minimize the perturbation to a conventional manufacturing process flow, while achieving the maximum possible reduction in effective dielectric constant.

U.S. Pat. Nos. 5,486,493 and 5,616,959 describe a process for fabricating multi-level interconnects. That process uses an etch-back step to planarize a low-k dielectric material before applying an oxide. It is difficult to achieve reliable tolerances using the etch-back step, and most manufacturing lines are not set up to implement an etch-back step.

### SUMMARY OF THE INVENTION

The present invention advances the state of the art directed to solving the aforementioned problems by providing a process for making a semiconductor device with a multi-level interconnect having an embedded low-dielectric constant (“low-k”) layer. According to the invented process, an organic low-k material is formed over a topographic substrate. A conventional dielectric insulator, such as silicon dioxide, is formed over the organic low-k material. The insulator is planarized using chemical-mechanical processing. Contact holes or vias are then etched into the two-layer dielectric stack.

Other features and advantages of the invention will become apparent from the following detailed description, taken in conjunction with the accompanying drawings, which illustrate, by way of example, the features of the invention.

### BRIEF DESCRIPTION OF THE DRAWING

In the drawing:

FIG. 1 illustrates narrow metal lines and wide metal regions patterned on a substrate;

FIG. 2 illustrates a low-k material spun on the topographical substrate depicted in FIG. 1;

FIG. 3 illustrates a thick oxide layer conformally deposited on the low-k material depicted in FIG. 2;

FIG. 4 illustrates use of a chemical-mechanical polishing process to planarize the oxide layer depicted in FIG. 3;

FIG. 5 illustrates a photoresist layer spun on the flat oxide layer depicted in FIG. 4 in a pattern that defines the location of vias;

FIG. 6 illustrates vias etched into the dielectric stack depicted in FIG. 5; and

FIG. 7 illustrates removal of the photoresist layer from the dielectric stack depicted in FIG. 6.

### DETAILED DESCRIPTION

For a better understanding of the invention, together with other and further objects, advantages, and capabilities thereof, reference is made to the following disclosure and the figures of the drawing, where like reference characters designate like or similar elements.

In this description, the symbol “k” means “dielectric constant” unless otherwise indicated.

Interconnect delay has become a significant factor limiting the clock-speed for advanced devices. As a result, technologists are motivated to integrate low-k dielectrics into back-end processing. To introduce low-k dielectrics requires that the low-k materials have excellent gap-fill capabilities to be compatible with Al (aluminum) metalization. Current targets for<0.18 micron CMOS Al-W (aluminum-tungsten) technologies include the use of an ILD (interlevel dielectric) with k below 2.8.

There are several commercially available spin-on organic polymers with k=2.5-2.8 and excellent gap-fill properties, including SiLK™ (i.e., “silicon low-k”, which is commercially available from the Dow Chemical Company), an aromatic hydrocarbon polymer, whose dielectric and mechanical properties are stable up to approximately 450° C. Planarizing the step-height produced by large metal pads is one of the challenges of working with spin-on materials.

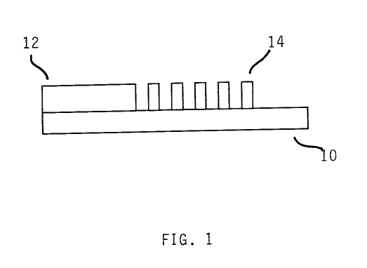

Referring to FIG. 1, the process for making the multi-level interconnect in the semiconductor device starts with metal features patterned on the first level of an oxide dielectric 10, creating a topographical substrate. The topographical substrate has a metal stack formed thereon. The metal stack has line-and-space patterns as well as wide metal regions which can be large metal pads 12 (or wide lines) and spaces between metal features that are two or more times wider than the spaces between the narrow lines 14. Some of the wider metal lines are used as bus lines because they have a lower electrical impedance. Such exemplary topography is an architecture with which the invention can be practiced, but is given by way of example and not limitation.

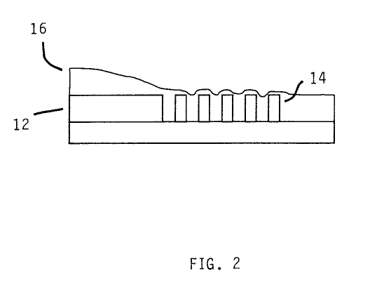

Referring to FIG. 2, an organic low-k dielectric material 16 is spun on the topographical substrate. The low-k dielectric material 16 fluidly fills in the spaces between metal lines 14 and the open space between pad 12 (or other wide metal region) and metal lines 14. Some of the low-k dielectric material 16 is carried by pad 12 or other wide metal region and the height of the low-k dielectric material is greater above the pad or other type of wide metal region. Low-k dielectric material 16 can include polymer dielectrics, inorganic dielectric materials, or carbon-doped SiO₂ (such as, for example, Black Diamond™0 which is commercially available from Applied Materials, Inc.).

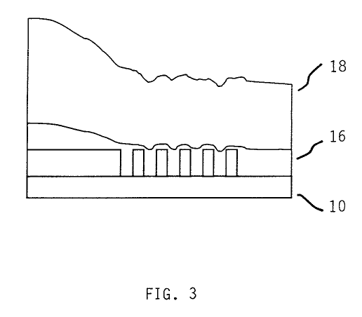

Referring to FIG. 3, a thick oxide layer of conventional dielectric material 18 (which in this embodiment is SiO₂) is deposited on low-k material 16. Oxide layer 18 deposits conformally and roughly assumes the topography of the low-k material 16 beneath the oxide layer.

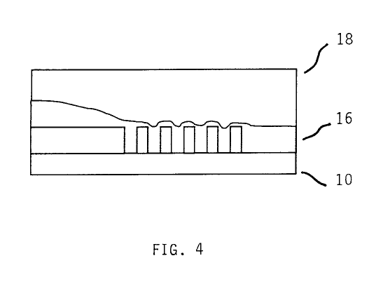

Referring to FIG. 4, oxide layer 18 is planarized using a CMP (chemical-mechanical polishing) process. Planarizing the oxide yields a flat surface on which integrated circuits can be made.

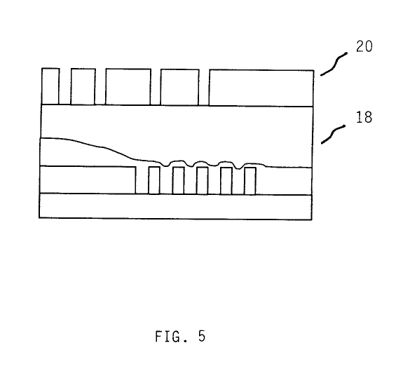

Referring to FIG. 5, a photoresist layer 20 is spun on the flattened oxide layer 18 and patterned by conventional means such as photolithography to define the pattern and location of the contact holes or vias.

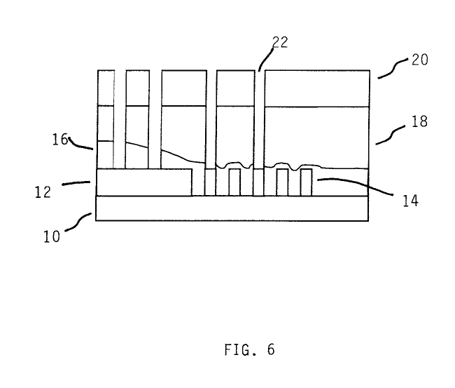

Referring to FIG. 6, vias are etched into the two dielectric layer stack, through oxide layer 18 and low-k material 16, to metal pad 12 and lines 14. A contact etching process is used to etch through both dielectric films. The contact etching process uses a high-density plasma reactor (or a medium-density reactor). In the contact etching process, the plasma chemistry and conditions are controlled to optimize the resultant features.

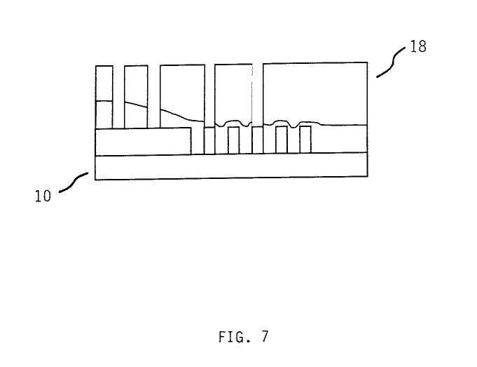

In the preferred embodiment, the layer 18 of SiO₂ is etched first. When the etch proceeds into the organic low-k material 16, the etching conditions, for example, RF power, pressure and gas mixture, may be changed to optimize the etching of each material. Photoresist layer 20 is then removed by conventional techniques, resulting in the multi-layer interconnect illustrated in FIG. 7.

The resulting multi-layer interconnect has a two-layer structure over the open areas, over the metal lines and over the wider metal pad. The multi-level interconnect has both spaced interconnect lines and an open area where the two-layer low-k material/SiO₂ stack is formed over both the spaced interconnect lines and the open area. The open areas are substantially filled with the organic low-k material. The multi-layer interconnect includes both inorganic and organic low-k materials.

Referring again to FIG. 2, the thickness of the spun-on low-k material 16 between narrow metal lines 14 is approximately the same as over unpatterned areas, but the step height between an unpatterned area and large metal pad 12 (or other type of wider metal region) is equal to the metal thickness. In conventional oxide processing, a very thick oxide layer is deposited and polished flat. It is difficult to perform a chemical-mechanical polishing of organic low-k materials because of their low modulus and tendency to scratch. A full-height low-k film is also difficult to integrate with W-plug (Tungsten-plug) formation in a via hole by CVD (chemical vapor deposition) because W CMP (Tungsten chemical mechanical polishing) requires stopping on the thin oxide mask or relatively soft organic low-k film. With regard to capacitance reduction, the primary benefit of the low-k material is to reduce the capacitance between adjacent lines, as compared to the reduction in parasitic capacitance between metal levels.

A relatively thin low-k film is used for gap-fill in the invented process for making the two-level dielectric stack. The thickness of the thin low-k film is selected such that the topography beneath the low-k film does not protrude through the low-k film. The low-k film is covered with a relatively thick oxide layer and then the oxide layer is chemical-mechanical polished. The thickness of the oxide layer is selected such that none of the low-k film protrudes through the oxide layer after chemical-mechanical polishing.

It is often the case that the intralayer distance between metal lines is smaller than the interlayer distance. In this case, the intralayer capacitance is highest. By first using a spin-on low-k material to fill in between the metal lines, one achieves the most benefit, in terms of capacitance reduction, from the low-k film when the low-k material is topped with a relatively thick layer Of SiO₂ (using conventional CVD technology), one can then continue processing the wafer by planarizing (typically with chemical-mechanical polishing) the oxide film. This is advantageous because it is often simpler and more reliable to CMP the oxide film rather than the low-k film.

The invented process eliminates the etchback step which relies on an etching process that etches film in open areas, but not in the small structures. The invented process thus results in the low-k material being retained over large metal pads.

While several particular forms of the invention have been illustrated and described, it will also be apparent that various modifications can be made without departing from the spirit and scope of the invention.

What is claimed is:

1. A process for making a multi-layer interconnect, comprising the steps of:
depositing a low-k dielectric material on a topographical substrate;
depositing an oxide on said low-k dielectric material;
planarizing said oxide using a CMP process; and
making via holes through said oxide and said low-k dielectric material.

2. The process of claim 1, wherein:
said low-k dielectric material is spun on said topographic substrate.

3. The process of claim 1, wherein:
oxide is SiO₂.

4. The process of claim 1, wherein:
making said via holes is performed by etching said oxide and then etching said low-k dielectric material.

5. The process of claim 1, wherein:
said oxide deposits conformally, thereby making a dielectric stack.

6. The process of claim 5, further comprising the steps of:
spinning on a photoresist layer that defines a pattern of vias; and
etching vias into said dielectric stack.

7. The process of claim 1, wherein:
said topographical substrate presents a pad and one or more lines.

8. A semiconductor device, comprising:
a topographical substrate that presents a metal pad, metal interconnect lines spaced from each other, and an open area between said metal pad and said metal lines; and
a two-layer dielectric stack that includes a low-k material and an oxide layer and being formed over both said spaced interconnect lines and said open area;
wherein said open area is substantially filled with said low-k material.

9. The device of claim 8, wherein:
said low-k material is an organic material.

10. The device of claim 8, wherein:
said oxide layer is SiO₂.
